(19) United States
(12) Patent Application Publication
(10) Pub. No.: US 2010/0154879 A1
(43) Pub. Date: Jun. 24, 2010

(54) Dye-Sensitized Solar Cell, Photo-Sensitized Anode Electrode Thereof, and Method of Manufacturing the Same

(75) Inventors: Chun-Chi Lai, Taipei City (TW); Yu-Chou Chao, Taipei City (TW); Wen-Hsien Ho, Keelung City (TW); Jui-Chi Lin, Tu-Chen City (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: TAIWAN TEXTILE RESEARCH INSTITUTE, Tu-Chen City (TW)

(21) Appl. No.: 12/345,963

(22) Filed: Dec. 30, 2008

(30) Foreign Application Priority Data
Dec. 22, 2008 (TW) 97150091

(51) Int. Cl. H01L 31/00

(52) U.S. Cl. 136/256; 427/74

(57) ABSTRACT

A dye-sensitized solar cell (DSSC), photo-sensitized anode electrode thereof, and method of manufacturing the same are disclosed, which includes the photo-sensitized anode electrode having a titanium dioxide layer coated by a protonized food dye layer that is an environmentally friendly photosensitizer instead of prior dyes. Therefore, the resultant DSSC can be recycled for reducing environmental pollution.

### RELATED APPLICATIONS

This application claims priority to Taiwan Application Serial Number 97150091, filed Dec. 22, 2008, which is herein incorporated by reference.

### FIELD OF THE INVENTION

This invention relates generally to a solar cell, and more particularly, to a dye-sensitized solar cell (DSSC), a photo-sensitized anode electrode thereof, and a method of manufacturing the same.

### BACKGROUND OF THE INVENTION

Since people raise the environmental awareness and other petroleum-related energies are going to exhaust, it is indeed necessary to develop a new and safe energy. A new energy must satisfy at least two requirements for worth developing, one of which is rich in reserves and difficultly exhausted, and the other of which is safe, clean, and friendly to human beings and nature environment. Regenerative energy, for example, solar energy, wind power, water power and so on, can satisfies the above two requirements. Besides, Taiwan lacks natural energy resources, and more than 90% of the required energy must be imported from other countries. However, Taiwan has enough sunlight and more insolation due to its location in the subtropical zone. It is advantageous to research and develop the solar energy in Taiwan, and the electric power converted by the solar energy is beneficial to save energy and environmental protection.

Utilizing solar cells (also called photovoltaic devices) is a direct way to convert the solar energy to energy. Nowadays, silicon (Si) semiconductor materials are utilized to produce most of commercialized solar cells. Si semiconductor materials are divided to single-crystal, poly-silicon, amorphous Si and so on according to the Si crystal states. The solar cells fabricated by using single-crystal Si have higher and stable energy conversion efficiency but cost expensively. The solar cells fabricated by using amorphous Si have lower energy conversion efficiency and shorter lifespan. Therefore, the dye-sensitized solar cell (DSSC) fabricated by organic materials such as polymers are more important to the academic and industrial circles.

The DSSC is also known as “Grätzel cell”, which is firstly invented by Michael Grätzel and Brian O'Regan of Swiss Federal Institute of Technology (École Polytechnique Fédérale de Lausanne) in 1991, and this research is titled as “A low-cost, high-efficiency solar cell based on dye-sensitized colloidal TiO₂ films”, published on Nature Vol. 353, No. 6346, pages 737-740 (1991).

The DSSC includes a transparent substrate having a titanium dioxide layer with a dye layer coated thereon, and the dye-sensitized titanium dioxide layer is the key technology for developing the DSSC. Under the light irradiation, electrons are injected into the dye absorbed on the titanium dioxide layer, transferred to the conduction band of the titanium dioxide layer, and then collected by the backward contact and brought out by outside circuits, so as to generate photocurrent. The titanium dioxide layer mainly absorbs the ultraviolet (UV) light, and its optoelectrical conversion efficiency can be effectively increased by absorbing the dye layer thereon, since the dye layer with higher molar extinction coefficient serves as a photosensitizer, absorbs other long wavelength light and reduces the length of electron path. In addition, to prevent the recombination of free electrons with the oxidized dye, the electrolyte of the DSSC includes redox couple of iodide (I⁻) and triiodide (I₃⁻), so as to quickly reduce the holes generated by the dye, thereby keeping the DSSC continuously operating.

Conventional dye layer is a material of ruthenium complex or mercurochrome dye. The ruthenium complex dye is, for example, N3 dye (cis-bis(isothiocyanato)bis(2,2′-bipyridyl-4,4′-dicarboxylato)-ruthenium (II); Ruthenium 535), N712 dye ((Bu₄N)₄[Ru(dcbpy)₂(NCS)₂] Complex), N719 dye (cis-bis(isothiocyanato)bis(2,2′-bipyridyl-4,4′-dicarboxylato)-ruthenium (ID bis-tetrabutylammonium; Ruthenium 535 bis-TBA), N749 dye (tris(isothiocyanato)-ruthenium (II)-2,2′:6′,2″-terpyridine-4,4′,4″-tricarboxylic acid, tris-tetrabutylammonium salt; Ruthenium 620-1H3TBA; 620 dye; black dye), ruthenium 470 dye (tris(2,2′-bipyridyl-4,4′-dicarboxylato)-ruthenium (II) dichloride; Ruthenium 470), ruthenium 505 dye (cis-bis(cyanido)(2,2′bipyridyl-4,4′-dicarboxylato)-ruthenium (II); Ruthenium 505), or Z907 dye (cis-bis(isothiocyanato)(2,2′-bipyridyl-4,4′-dicarboxylato)(2,2′-bipyridyl-4,4′-di-nonyl)-ruthenium (II); Ruthenium 520-DN). However, the ruthenium complex or mercurochrome dye is environmentally unfriendly due to heavy metal included therein, as well as that it is complicated in processing and costs expensively.

Hence, it is necessary to provide an environmentally friendly dye applied in the photo-sensitized anode electrode of the DSSC, so as to improve the prior dyes that are environmentally unfriendly, process complicatedly, cost more and so on.

### SUMMARY OF THE INVENTION

Accordingly, it is an aspect of the present invention to provide a photo-sensitized anode electrode of a DSSC and a method of manufacturing the same, which includes the anode electrode having a titanium dioxide layer coated by a protonized food dye layer that is an environmentally friendly photosensitizer instead of prior dyes. Therefore, the resultant DSSC can be recycled for reducing environmental pollution.

It is another aspect of the present invention to provide a DSSC, which includes an anode electrode having a titanium dioxide layer coated by a protonized food dye layer that is an environmentally friendly photosensitizer instead of prior dyes. Therefore, the resultant DSSC can be recycled for reducing environmental pollution.

According to the aforementioned aspect of the present invention, a photo-sensitized anode electrode of a DSSC is provided. The photo-sensitized anode electrode may include a transparent substrate, a titanium dioxide layer and a protonized food dye layer. The titanium dioxide layer may be disposed on the transparent substrate, and the protonized food dye layer may be disposed on the titanium dioxide layer.

In an embodiment of the present invention, the food dye may be, for example, a triarylmethane dye or an azo dye.

Examples of the triarylmethane dye may include but not be limited in Food Yellow 13 (color index number (C.I. No.) 47005; sodium 2-(1,3-dioxo-2,3-dihydro-1H-inden-2-yl)-1,4-dihydroquinoline-6-sulfonate; C.I. Food Y-13; Quinoline Yellow), Food Red 14 (C.I. No. 45430; disodium 2-(2,4,5,7-tetraiodo-3-oxidooxoxanthen-9-yl)benzoate monohydrate; C.I. Food R-14; Erythrosine), Food Blue 5 (C.I. No. 42051; [4-(α-(4-diethylaminophenyl)-5-hydroxy-2,4-disulfophenyl-methylidene)-2,5-cyclohexadien-1-ylidene]diethylammonium hydroxide inner salt; C.I. Food B-5; Patent Blue V), Food Green 3 (C.I. No. 42053; N-Ethyl-N-[4-[[4-[ethyl[(3-sulfophenyl)methyl]amino]phenyl](4-hydroxy-2-sulfophen yl)methylene]-2,5-cyclohexadien-1-ylidene]-3-sulfo-benzenemethanaminium hydroxide inner salt disodium salt; C.I. Food G-3), or Food Green 5 (C.I. No. 61570; [[(N,N-4-dimethylaminophenyl)-2-hydroxy-3,6-disulfonato-1-naphthyl-methylidene]-2,5-cyclohexadien-1-ylidene]dimethylammonium hydroxide inner salt sodium salt; C.I. Food G-5).

Examples of the azo dye may include but not be limited in Food Red 3 (C.I. No. 14720; Disodium 4-hydroxy-3-(4-sulfonato-1-nephthylazo)naphthalene-1-sulfonate; C.I. Food R-3; Carmoisine), Food Red 9 (C.I. No. 16185; Trisodium 2-hydroxy-1-(4-sulfonato-1-naphthylazo)naphthalene-3,6-disulfonate; C.I. Food R-9; Amaranth), or Food Black 1 (C.I. No. 28440; Tetrasodium 1-acetamido-2-hydroxy-3-(4-((4-sulphonatophenylazo)-7-sulphonato-1-naphthylazo))naphthalene-4,6-disulphonate; C.I. Food Blk-1; Black Pn).

In an embodiment of the present invention, the triarylmethane dye is the Food Yellow 13 or the Food Red 14.

According to another aforementioned aspect of the present invention, a method of manufacturing a photo-sensitized anode electrode of a DSSC is provided. First of all, a transparent substrate is provided, in which the transparent substrate may be made of glass or plastic. Next, a titanium dioxide layer is formed on the transparent substrate. And then, a protonized food dye layer is formed on the titanium dioxide layer. The step of forming the protonized food dye may further include performing a salt-out step, a dissolving step, a protonizing step and a soaking step.

In an embodiment of the present invention, the salt-out step may include that a food dye is added into a saturated saline solution for obtaining a first crystal, in which the food dye may be, for example, a triarylmethane dye or an azo dye. The triarylmethane dye may include but not be limited in Food Yellow 13 (C.I. Food Y-13), Food Red 14 (C.I. Food R-14), Food Blue 5 (C.I. Food B-5), Food Green 3 (C.I. Food G-3), or Food Green 5 (C.I. Food G-5). The azo dye may include but not be limited in Food Red 3 (C.I. Food R-3), Food Red 9 (C.I. Food R-9), or Food Black 1 (C.I. Food Blk-1).

In an embodiment of the present invention, the dissolving step may include that the first crystal is dissolved in water, so as to obtain a first solution containing the first crystal.

In an embodiment of the present invention, the protonizing step may include that a first acid is slowly added into the first solution containing the first crystal, so as to obtain a second crystal, in which the second crystal is a protonized food dye.

In an embodiment of the present invention, the soaking step may include that the transparent substrate having the titanium dioxide layer is soaked into a second solution that contains the second crystal dissolved in an organic solvent, so as to form a protonized food dye layer on the titanium dioxide layer.

In an embodiment of the present invention, the acid may be, for example, nitric acid, sulfuric acid, phosphoric acid or hydrochloric acid.

In an embodiment of the present invention, the organic solvent may be, for example, methanol, ethanol or propanol.

According to the aforementioned aspect of the present invention, a DSSC is provided. The DSSC may include a photo-sensitized anode electrode, a cathode electrode, and an electrolyte layer disposed between the photo-sensitized anode and the cathode electrodes. The photo-sensitized anode electrode may include a transparent substrate, a titanium dioxide layer and a protonized food dye layer. The titanium dioxide layer may be disposed on the transparent substrate, and the protonized food dye layer may be disposed on the titanium dioxide layer. The food dye may be a triarylmethane dye or an azo dye. The triarylmethane dye may include but not be limited in Food Yellow 13 (C.I. Food Y-13), Food Red 14 (C.I. Food R-14), Food Blue 5 (C.I. Food B-5), Food Green 3 (C.I. Food G-3), or Food Green 5 (C.I. Food G-5). The azo dye may include but not be limited in Food Red 3 (C.I. Food R-3), Food Red 9 (C.I. Food R-9), or Food Black 1 (C.I. Food Blk-1).

In an embodiment of the present invention, the cathode electrode may be made of a material of platinum, gold, carbon or an electrically conductive polymer.

In an embodiment of the present invention, the electrolyte layer is a liquid-, gel- or solid-state, and the electrolyte layer may include an acetonitrile solution containing iodine, lithium iodide and 4-isobutyl pyridine.

With application to the aforementioned DSSC, the photo-sensitized anode electrode thereof, and the method of manufacturing the same of the present invention, they include the photo-sensitized anode electrode having a titanium dioxide layer coated by the protonized food dye that is an environmentally friendly photosensitizer instead of prior dyes, resulting in the DSSC can be recycled for reducing environmental pollution.

### DETAILED DESCRIPTION OF THE PREFERRED EMBODIMENT

Accordingly, the present invention provides a DSSC, a photo-sensitized anode electrode thereof, and a method of manufacturing the same, which include the photo-sensitized anode electrode having a titanium dioxide layer coated by the protonized food dye that is an environmentally friendly photosensitizer instead of prior dyes.

Food Dye As Photosensitizer

In detail, the DSSC may include a transparent substrate, a titanium dioxide layer and a protonized food dye layer. The titanium dioxide layer may be disposed on the transparent substrate, in which the transparent substrate may include a patterned circuit layer, and the protonized food dye layer may be disposed on the titanium dioxide layer. In an embodiment, a suitable food dye may be, for example, a triarylmethane dye or an azo dye. Examples of the triarylmethane dyes may be referred to Table 1, and examples of the azo dyes may be referred to Table 2. However, it is stated that, various countries have their own rules for nomenclature and number of food dyes, and a particular food dyes may have various names and indices in various countries or regions. To avoid unnecessary confusion, the Society of Dyers and Colourists and the American Association of Textile Chemists and Colorists had jointly edited and published a “Colour Index (C.I.) International” as a reference database, and the C.I. numbers (C.I. No.) serve as common references of manufactured color products.

TABLE 1
Examples of the triarylmethane dyes

| C.I. | | | Product |
|---|---|---|---|
| No. | Generic Name | Chemical name | name |
| 47005 | Food Yellow 13 | sodium 2-(1,3-dioxo-2,3-dihydro- | Quinoline |
| | (C.I. Food Y-13) | 1H-inden-2-yl)-1,4-dihydroquinoline-6-sulfonate | Yellow |
| 45430 | Food Red 14 | disodium 2-(2,4,5,7-tetraiodo-3- | Erythrosine |
| | (C.I. Food R-14) | oxidooxoxanthen-9-yl) benzoate | |
| | | monohydrate | |
| 42051 | Food Blue 5 | [4-(α-(4-diethylaminophenyl)-5-hydroxy- | Patent Blue V |
| | (C.I. Food B-5) | 2,4-disulfophenyl-methylidene)-2,5- | |
| | | cyclohexadien-1-ylidene] diethylammonium | |
| | | hydroxide inner salt | |
| 42053 | Food Green 3 | N-Ethyl-N-[4-[[4-[ethyl [(3-sulfophenyl) | |
| | (C.I. Food G-3) | methyl]amino]phenyl](4-hydroxy-2- | |
| | | sulfophenyl) methylene]-2,5- | |
| | | cyclohexadien-1-ylidene]-3-sulfo- | |
| | | benzenemethanaminium hydroxide | |
| | | inner salt disodium salt | |
| 61570 | Food Green 5 | [[(N,N-4-dimethylaminophenyl)-2- | |
| | (C.I. Food G-5) | hydroxy-3,6-disulfonato-1-naphthyl- | |
| | | methylidene]-2,5-cyclohexadien-1- | |
| | | ylidene] dimethylammonium hydroxide | |
| | | inner salt sodium salt | |

TABLE 2
Examples of the azo dyes

| | | | Product |
|---|---|---|---|
| C.I. No. | Generic Name | Chemical name | name |
| 14720 | Food Red 3 | Disodium 4-hydroxy-3- | Carmoisine |
| | (C.I. Food R-3) | (4-sulfonato-1-nephthylazo)naphthalene-1-sulfonate | |
| 16185 | Food Red 9 | Trisodium 2-hydroxy-1-(4-sulfonato-1-naphthylazo) | Amaranth |
| | (C.I. Food R-9) | naphthalene-3,6-disulfonate | |
| 28440 | Food Black 1 | Tetrasodium 1-acetamido- | Black Pn |
| | (C.I. Food | 2-hydroxy-3-(4-((4-sulphonatophenylazo)-7- | |
| | Blk-1) | sulphonato-1-naphthylazo)) naphthalene- | |
| | | 4,6-disulphonate | |

In another embodiment, the food dye may be the triarylmethane dye, for example, the Food Yellow 13 or the Food Red 14.

In the embodiments of the present invention, several food dyes serving as photosensitizers instead of prior dyes, are applied in the manufacture of a photo-sensitized anode electrode. Hereinafter, the method of manufacturing the photo-sensitized anode electrode is exemplified as follows.

Method of Manufacturing Photo-Sensitized Anode Electrode of DSSC

In an embodiment, the photo-sensitized anode electrode is produced as follow. First of all, a transparent substrate is provided, in which the transparent substrate may be made of glass or plastic, and the transparent substrate comprises a patterned circuit layer. Next, a titanium dioxide layer is formed on the transparent substrate, in which the titanium dioxide layer can be produced by prior arts, for example, sol-gel method accompanying with spin- or blade-coating on the transparent substrate; or, directly forming the titanium dioxide layer on the transparent substrate by a hydrothermal method, a co-precipitation method, a dip-coating method, a sputtering method, a chemical vapor deposition (CVD); or alternatively, a commercial titanium dioxide powder directly dispersed in ethanol solution and coating on the transparent substrate. The formation and coating method of the titanium dioxide layer are understood by one person skilled in the art, and thus the related details are unnecessary to be addressed herein.

And then, a protonized food dye layer is formed on the titanium dioxide layer. In an embodiment, the step of forming the protonized food dye layer may further include performing a salt-out step, a dissolving step, a protonizing step and a soaking step. Moreover, in this embodiment, the salt-out step may include that a food dye is added into a saturated saline solution for obtaining a first crystal, in which the food dye may be a triarylmethane dye or an azo dye. The triarylmethane dyes and the azo dyes are exemplified as above, and thus the related details are unnecessary to be addressed herein. And then, the dissolving step is performed and includes that the first crystal is dissolved in water, so as to obtain a first solution containing the first crystal. Later, the protonizing step is performed and includes that a first acid is slowly added into the first solution containing the first crystal, so as to obtain a second crystal, in which the second crystal is a protonized food dye, and the suitable acid may be, for example, nitric acid, sulfuric acid, phosphoric acid or hydrochloric acid. In another embodiment, the suitable acid may be hydrochloric acid. Subsequently, the soaking step is performed and includes that the transparent substrate having the titanium dioxide layer is soaked into a second solution which contains the second crystal dissolved in an organic solvent, so as to form a protonized food dye layer on the titanium dioxide layer, in which the organic solvent may be, for example, methanol, ethanol or propanol. In another embodiment, the organic solvent is methanol.

The resulted photo-sensitized anode electrode can be further assembled with a cathode electrode and an electrolyte layer, so as to form a DSSC. Thereinafter, the assembly of the DSSC is exemplified as follows.

Assembly of DSSC

The DSSC may include a photo-sensitized anode electrode, a cathode electrode, and an electrolyte layer disposed between the photo-sensitized anode and the cathode electrodes, in which the photo-sensitized anode electrode is described as above rather than addressing the related details herein. In an embodiment, the cathode electrode may be made of a material including but not being limited in platinum, gold, carbon or an electrically conductive polymer, in which the electrically conductive polymer may be, for example, polypyrrole, polyaniline or polythiophene. In an embodiment, the electrolyte layer is a liquid-, gel- or solid-state, and the electrolyte layer may include an acetonitrile solution containing iodine, lithium iodide and 4-isobutyl pyridine.

It is worth mentioning that the photo-sensitized anode of the DSSC of the present invention utilizes the purified and protonized food dye that is an environmentally friendly photosensitizer instead of prior dyes, for example, Ruthenium complex dyes (N3 dye, N719 dye or the like) or mercurochrome dye. Most food dyes utilized in the present invention are water-soluble coal-tar dyes, which are beneficial to be easily obtained and processed, as well as that the resulted DSSC can be recycled for reducing environmental pollution.

Thereinafter, various applications of the present invention will be described in more details referring to several exemplary embodiments below, while not intended to be limiting. Thus, one skilled in the art can easily ascertain the essential characteristics of the present invention and, without departing from the spirit and scope thereof, can make various changes and modifications of the invention to adapt it to various usages and conditions.

### EXAMPLE 1

### Preparation of Purified and Protonized Food Dyes

EXAMPLE 1 is related to prepare purified and protonized food dyes. Firstly, since most commercial food dyes contain additives, each commercial food dye listed in Tables 1 and 2 is necessarily added into a saturated saline solution, stirred and heated to 80° C., and kept stirring at the same temperature for 30 minutes. Next, the saturated saline solution containing the food dye is cooled to the room temperature so as to precipitate a crystal. Later, the filtrated crystal is the purified food dye. Therefore, the water-soluble impurities in the commercial food dyes can be removed.

Secondly, since most commercial food dyes contain metal cations, for example, sodium ion (Na⁺), potassium ion (K⁺) and calcium ion (Ca²⁺), and other metal cations may be added into the food dyes in the aforementioned salt-out step. In order to prevent the metal cations from being disadvantageous to electron transfer in the solar cell and coloring to the titanium dioxide, it is necessary to employ protons (H⁺) for replacing the metal cations in the food dyes. Such treatment is referred as a protonizing step. At first, 0.5 g of the aforementioned purified food dye is dissolved in 20 mL of water, stirred and heated to 80° C. Next, 30 mL of 38% hydrochloric acid is slowly added into the aqueous solution containing the purified food dye crystal, so as to obtain another crystal (if there is no crystal salted-out in this step, the purified food dye crystal is added into the saturated saline solution again). Subsequently, another crystal is filtrated and re-crystallized by methanol, so as to obtain the purified and protonized food dye.

A spectrometry instrument (for example, Hitachi U-4100 spectrometry instrument) is employed to further measure absorption spectra of the purified and protonized food dyes at the full visible wavelength range. Reference is made to Table 3, which is the absorption index integration data calculated by the molar absorption coefficient (ε) and the full visible wavelength range of purified and protonized food dyes the according to an embodiment of the present invention. The “absorption index integration at the full visible wavelength range” is referred to the area under the curve of the absorption spectrum of each food dye using integration, in the unit of “ABS * nm”, for evaluating a light-absorption efficiency of each food dye.

According to the result of Table 3, Food Green 3 has the higher molar absorption coefficient, Food Blue 5 has the second higher one, and Food Red 3 has the lower one. Besides, Food Blue 5 has the higher light absorption index integration value at the full visible wavelength range, Food Green 3 has the second higher one, and Food Red 3 has the lower one. However, according to the chemical structure formula of each food dye, the food dye having triarylmethane or azo group in its chemical structure has higher molar absorption coefficient and higher light absorption index integration value at the full visible wavelength range. The main reason may be that the triarylmethane or azo group is highly light-absorbing chromophore and has many auxochromes in its chemical structure. The triarylmethane or azo group of the food dye can enhance light absorption, and the light absorption index increases while the maximum absorption wavelength of the food dye is shifted to long wavelength.

TABLE 3

| | maximum | | light absorption |
|---|---|---|---|
| | absorption | | index |
| | wavelength, | molar absorption | integration value at the |
| | λₘₐₓ | coefficient, ε | full visible wavelength |
| Food Yellow | 412 | 0.182 × 10⁵ | 74.55 |
| 13 | | | |
| Food Red 3 | 516 | 0.112 × 10⁵ | 32.43 |
| Food Red 9 | 521 | 0.255 × 10⁵ | 82.79 |
| Food Red 14 | 527 | 0.866 × 10⁵ | 94.30 |
| Food Blue 1* | 610 | 0.182 × 10⁵ | 41.41 |
| Food Blue 5 | 638 | 0.9416 × 10⁵ | 160.83 |
| Food Green 3 | 624 | 1.3232 × 10⁵ | 105.79 |
| Food Green 5 | 635 | 0.8596 × 10⁵ | 158.91 |
| Food Black 1 | 573 | 0.374 × 10⁵ | 127.21 |

*Food Blue 1 (C.I. No. 73015; disodium 3,3′-dioxo-2,2′-bi-indolylidene-5,5′-disulphonate; C.I. Food B-1; indigo carmine)

### EXAMPLE 2

### Preparation of Titanium Dioxide Membrane Electrode

EXAMPLE 2 is related to prepare a titanium dioxide membrane electrode. In this example, first of all, 95 wt. % ethanol solution serves as a dispersion, and commercial titanium dioxide powder (Aeroxide®, Evonik Industries AG, Germany; old product name: Degussa P-25; purity: >99.5%) is mixed and stirred well into the ethanol solution, so as to obtain a slurry with a solid content of 15 wt. %.

Next, the slurry is blade-coated on a transparent glass or plastic substrate having indium tin oxide (ITO) (the plastic substrate may be made of poly(ethylene terephthalate) (PET), for example), and then the coated transparent substrate is placed and dried for about 30 minutes. Afterward, the coated transparent substrate is dried on a hot plate under about 50° C. for 10 minutes, so as to obtain the titanium dioxide membrane electrode

### EXAMPLE 3

### Preparation of Photo-Sensitized Anode Electrode Using Food Dye

EXAMPLE 3 is related to prepare a photo-sensitized anode electrode using food dye photosensitizer. At first, in this example, the membrane electrode produced by EXAMPLE 2 is soaked into the ethanol solution of 5×10⁻⁴ M food dye of EXAMPLE 1 for 10 to 14 hours; and alternatively, the membrane electrode produced by EXAMPLE 2 is soaked into the ethanol solution with 5×10⁻⁴ M food dye of EXAMPLE 1 for about 12 hours, so as to form food dye layer on the titanium dioxide layer. Next, the food dye absorbing membrane electrode is taken out, roughly rinsed by ethanol and dried, so as to obtain the photo-sensitized anode electrode using food dye photosensitizer, in which the purified and protonized food dye layer is disposed on the titanium dioxide layer of the photo-sensitized anode electrode.

### EXAMPLE 4

### Preparation of DSSC

EXAMPLE 4 is related to prepare a DSSC. At first, in this example, the photo-sensitized anode electrode serves as an anode, and a cathode electrode is disposed separately opposing to the photo-sensitized anode, in which the cathode electrode includes another conductive substrate coated with platinum. An electrolyte is filled between the photo-sensitized anode and the cathode electrode, so as to obtain the DSSC with a general sandwich structure. The electrolyte comprises an acetonitrile (ALDRICH; purity: 99.5%) solution containing 0.05 M iodine (MERCK; purity: 99.8%), 0.5 M lithium iodide (MERCK; purity: >99.8%) and 0.05M 4-isobutyl pyridine.

### EXAMPLE 5

### Evaluation of Optoelectrical Characteristics of DSSC

EXAMPLE 4 is related to evaluate optoelectrical characteristics of DSSC, for example, short circuit current (Isc), open circuit voltage (Voc), fill factor (FF) and solar energy to electricity conversion efficiency (η). In this example, a 450 W xenon (Xe) short arc lamp (Lot-Oriel Ltd.) serves as a light source of the system for evaluating the DSSC performance, a filter serves to modify the spectral output of the Xe short arc lamp to match solar conditions for providing a simulated solar radiation, and a photodetector (Optical Power meter, Solar Light Company, Inc. PMA-2141) serves to adjust the simulated solar radiation to 100 W/cm² of light intensity. After the light source is stable, the DSSC of EXAMPLE 4 is irradiated under the beam from the adjusted light source and electrically connected to positive and negative terminals of a power supply that provides a positive voltage controlled by a sourcemeter. The output current of the DSSC is measured to obtain a current-voltage (I-V) curve and optoelectrical characteristics, for example, short circuit current (Isc), open circuit voltage (Voc), fill factor (FF) and solar energy to electricity conversion efficiency (η). The results of the optoelectrical characteristics are listed as below as Tables 5 and 6.

The “short circuit current (Isc)” herein is referred to a working current of a solar cell under the short circuit condition, and also referred to a “short circuit light current”, which is equal to an absolute quantity of photons converting to electron-hole pairs, while the output voltage of the solar cell is zero. Typically, the higher short circuit current of the solar cell is better.

The “open circuit voltage (Voc)” herein is referred to a working current of a solar cell under the open circuit condition, while the output current of the solar cell is zero. Typically, the higher open circuit voltage of the solar cell is better.

The “fill factor (FF)” herein is referred to a ratio of a maximum output power (Pₘₐₓ=(I×V)ₘₐₓ) of a solar cell circuit, with respect to a maximum output power (the multiplied product of Voc and Isc) of a solar cell, while the output current of the solar cell is zero. Typically, the higher open circuit voltage of the solar cell is better:

$$F F = \frac{{P}_{max}}{{I}_{SC} \times {V}_{OC}} = \frac{{( I \times V )}_{max}}{{I}_{SC} \times {V}_{OC}} \qquad ( I )$$

The “solar energy to electricity conversion efficiency (η)” herein is referred to a percentage of a maximum output power (Pₘₐₓ) of a light receiving unit area of a solar cell with respect to an energy density of the emitted sunlight (P_{light}), and it is obtained by the following formula (II). Typically, the expected value of the solar energy to electricity conversion efficiency of a solar cell is 1, but the actual one is less than 1. The higher solar energy to electricity conversion efficiency is better:

$$η ( \% ) = \frac{{( I \times V )}_{max}}{{P}_{light}} \times 100 \% \qquad ( II )$$

Reference is made to Table 4, which is the optoelectrically performance data of the DSSC according to an embodiment of the present invention, wherein the food dye layer of the photo-sensitized anode electrode of the DSSC is purified and protonized by using the method of EXAMPLE 1. According to the result of Table 4, the DSSC having Food Yellow 13 or Food Red 14 photosensitizer has short circuit current (Isc) of about 0.18 mA/cm², and the DSSCs having other food dye photosensitizers have Isc ranging from 0.04 mA/cm² to 0.08 mA/cm². Moreover, the DSSC having Food Yellow 13 has the open circuit voltage (Voc) of about 210 mV; the second is the DSSC having Food Red 14 with Voc of about 160 mV; and the DSSC having Food Blue 5 and Food Green 3 have Voc of 120 mV and 100 mV, respectively. However, the DSSCs having other food dye photosensitizers have lower Voc. Furthermore, the DSSC having Food Yellow 13 has the solar energy to electricity conversion efficiency (η) of about 0.01333%; the second is the DSSC having Food Red 14 has η of about 0.0096%; however, the DSSCs having other food dye photosensitizers have lower η. Additionally, the DSSC having Food Yellow 13 has the average power density of about 0.36 W/h□cm² (while it has a voltage of 0.11 V and a current of 9.23×10⁻⁵ A/cm²) higher than the no-load power consumption of commercial mobile phone (about 0.012 W/h of Nokia N73 or Nokia 2310, for example). Therefore, the DSSC of EXAMPLE 4 is certainly applied to commercial mobile phones and other portable 3C products.

TABLE 4

| | | | | | Average |
|---|---|---|---|---|---|
| | Isc | | | | power density |
| | (mA/cm²) | Voc (mV) | FF | η(%) | (W/h□cm²) |
| Food Yellow | 0.18 | 210 | 0.27 | 0.0133 | 0.0360 |
| 13 | | | | | |
| Food Red 3 | 0.04 | 30 | 0.19 | 0.0003 | 0.0008 |
| Food Red 9 | 0.04 | 30 | 0.23 | 0.0004 | 0.0010 |
| Food Red 14 | 0.18 | 160 | 0.26 | 0.0100 | 0.0270 |
| Food Blue 5 | 0.06 | 120 | 0.22 | 0.0023 | 0.0057 |
| Food Green 3 | 0.08 | 100 | 0.28 | 0.0029 | 0.0081 |
| Food Green 5 | 0.04 | 30 | 0.19 | 0.0003 | 0.0008 |
| Food Black 1 | 0.04 | 50 | 0.18 | 0.0005 | 0.0013 |

Since the present invention utilizes food dyes which are mostly water-soluble coal-tar dyes and are beneficial to be easily obtained and processed, purified and protonized to remove the metal cations included therein, and the resulted DSSC using those food dyes can be recycled for reducing environmental pollution. However, it is worth mentioning that, it is not assumed that other food dyes excepted from the ones listed herein are inevitably applied in the photosensitizer of the photo-sensitized anode electrode of the DSSC while the food dyes are purified and protonized as the present method. The reason is that, the gap energy between the titanium dioxide layer and the food dye absorbed thereon is necessary matched. Even though the food dye has higher light-absorption coefficient, it cannot enhance the solar energy to electricity conversion efficiency of the DSSC if the gap energy is not matched between the titanium dioxide layer and the food dye absorbed thereon. Besides, even though the DSSC utilizes several food dyes having different light-absorption coefficients, it is not certainly better that the one using a single food dye in the solar energy to electricity conversion efficiency.

By the way, it is necessarily supplemented that, the specific food dyes, the specific purifying and protonizing methods, the specific transparent substrate, the specific cathode electrode, the specific electrolyte and the like are employed as exemplary embodiments in the present invention for evaluating the DSSC and the photo-sensitized anode electrode of the present invention, however, as is understood by a person skilled in the art, the different food dyes, different purifying and protonizing methods, different transparent substrates, different cathode electrodes and different electrolytes can be employed in the present invention and be any combined thereof rather than limiting to the aforementioned examples.

According to the preferred embodiments of the present invention, the aforementioned DSSC, the photo-sensitized anode electrode thereof, and the method of manufacturing the same of the present invention, which advantageously include the photo-sensitized anode electrode having a titanium dioxide layer coated by the protonized food dye that is an environmentally friendly photosensitizer instead of prior dyes, resulting in the DSSC can be recycled for reducing environmental pollution.

As is understood by a person skilled in the art, the foregoing preferred embodiments of the present invention are illustrated of the present invention rather than limiting of the present invention. It is intended to cover various modifications and similar arrangements included within the spirit and scope of the appended claims. Therefore, the scope of which should be accorded to the broadest interpretation so as to encompass all such modifications and similar structure.

What is claimed is:

1. A photo-sensitized anode electrode of a dye-sensitized solar cell (DSSC), comprising:
a transparent substrate;
a titanium dioxide layer disposed on the transparent substrate; and
a protonized food dye layer disposed on the titanium dioxide layer, wherein the food dye is a triarylmethane dye or an azo dye,
the triarylmethane dye is selected from the group consisted of Food Yellow 13 (color index number (C.I. No.) 47005; sodium 2-(1,3-dioxo-2,3-dihydro-1H-inden-2-yl)-1,4-dihydroquinoline-6-sulfonate; C.I. Food Y-13; Quinoline Yellow), Food Red 14 (C.I. No. 45430; disodium 2-(2,4,5,7-tetraiodo-3-oxidooxoxanthen-9-yl)benzoate monohydrate; C.I. Food R-14; Erythrosine), Food Blue 5 (C.I. No. 42051; [4-(α-(4-diethylaminophenyl)-5-hydroxy-2,4-disulfophenyl-methylidene)-2,5-cy clohexadien-1-ylidene]diethylammonium hydroxide inner salt; C.I. Food B-5; Patent Blue V), Food Green 3 (C.I. No. 42053; N-Ethyl-N-[4-[[4-[ethyl[(3-sulfophenyl)methyl]amino]phenyl](4-hydroxy-2-sulfophenyl)methylene]-2,5-cyclohexadien-1-ylidene]-3-sulfo-benzenemethanaminium hydroxide inner salt disodium salt; C.I. Food G-3), and Food Green 5 (C.I. No. 61570; [[(N,N-4-dimethylaminophenyl)-2-hydroxy-3,6-disulfonato-1-naphthyl-methylidene]-2,5-cyclohexadien-1-ylidene]dimethylammonium hydroxide inner salt sodium salt; C.I. Food G-5), and
the azo dye is selected from the group consisted of Food Red 3 (C.I. No. 14720; Disodium 4-hydroxy-3-(4-sulfonato-1-nephthylazo)naphthalene-1-sulfonate; C.I. Food R-3; Carmoisine), Food Red 9 (C.I. No. 16185; Trisodium 2-hydroxy-1-(4-sulfonato-1-naphthylazo)naphthalene-3,6-disulfonate; C.I. Food R-9; Amaranth), and Food Black 1 (C.I. No. 28440; Tetrasodium 1-acetamido-2-hydroxy-3-(4-((4-sulphonatophenylazo)-7-sulphonato-1-naphthy lazo))naphthalene-4,6-disulphonate; C.I. Food Blk-1; Black Pn).

2. The photo-sensitized anode electrode of the DSSC according to claim 1, wherein the triarylmethane dye is the Food Yellow 13 or the Food Red 14.

3. The photo-sensitized anode electrode of the DSSC according to claim 1, wherein the transparent substrate is made of glass or plastic.

4. The photo-sensitized anode electrode of the DSSC according to claim 1, wherein the transparent substrate comprises a patterned circuit layer.

5. A photo-sensitized anode electrode of a DSSC, comprising:
a transparent substrate;
a titanium dioxide layer disposed on the transparent substrate; and
a protonized food dye layer disposed on the titanium dioxide layer, wherein the food dye is Food Yellow 13.

6. The photo-sensitized anode electrode of the DSSC according to claim 5, wherein the transparent substrate is made of glass or plastic.

7. The photo-sensitized anode electrode of the DSSC according to claim 5, wherein the transparent substrate comprises a patterned circuit layer.

8. A photo-sensitized anode electrode of a DSSC, comprising:
a transparent substrate;
a titanium dioxide layer disposed on the transparent substrate; and
a protonized food dye layer disposed on the titanium dioxide layer, wherein the food dye is Food Red 14.

9. The photo-sensitized anode electrode of the DSSC according to claim 8, wherein the transparent substrate is made of glass or plastic.

10. The photo-sensitized anode electrode of the DSSC according to claim 8, wherein the transparent substrate comprises a patterned circuit layer.

11. A method of manufacturing a photo-sensitized anode electrode of a DSSC, comprising:
providing a transparent substrate;
forming a titanium dioxide layer disposed on the transparent substrate;
forming a protonized food dye layer disposed on the titanium dioxide layer, wherein the step of forming the protonized food dye further comprises:
performing a salt-out step, wherein a food dye is added into a saturated saline solution for obtaining a first crystal, wherein the food dye is a triarylmethane dye or an azo dye, the triarylmethane dye is selected from the group consisted of Food Yellow 13, Food Red 14, Food Blue 5, Food Green 3, Food Green 5, and the azo dye is selected from the group consisted of Food Red 3, Food Red 9, and Food Black 1;
performing a dissolving step to dissolving the first crystal in water, so as to obtain a first solution containing the first crystal;
performing a protonizing step to add an acid slowly into the first solution containing the first crystal, so as to obtain a second crystal, wherein the second crystal is a protonized food dye; and
soaking the transparent substrate having the titanium dioxide layer into a second solution that contains the second crystal dissolved in an organic solvent, so as to form a protonized food dye layer on the titanium dioxide layer.

12. The method of manufacturing the photo-sensitized anode electrode of the DSSC according to claim 11, wherein the triarylmethane dye is the Food Yellow 13 or the Food Red 14.

13. The method of manufacturing the photo-sensitized anode electrode of the DSSC according to claim 11, wherein the transparent substrate is made of glass or plastic.

14. The method of manufacturing the photo-sensitized anode electrode of the DSSC according to claim 11, wherein the transparent substrate comprises a patterned circuit layer.

15. The method of manufacturing the photo-sensitized anode electrode of the DSSC according to claim 11, wherein the acid is nitric acid, sulfuric acid, phosphoric acid or hydrochloric acid.

16. The method of manufacturing the photo-sensitized anode electrode of the DSSC according to claim 11, wherein the organic solvent is methanol, ethanol or propanol.

17. The method of manufacturing the photo-sensitized anode electrode of the DSSC according to claim 11, wherein the soaking step is performed in 10 to 14 hours.

18. The method of manufacturing the photo-sensitized anode electrode of the DSSC according to claim 11, wherein the soaking step is performed in 12 hours.

19. A DSSC, comprising:
a photo-sensitized anode electrode comprising:
a transparent substrate;
a titanium dioxide layer disposed on the transparent substrate; and
a protonized food dye layer disposed on the titanium dioxide layer, wherein the food dye is a triarylmethane dye or an azo dye, the triarylmethane dye is selected from the group consisted of Food Yellow 13, Food Red 14, Food Blue 5, Food Green 3, Food Green 5, and the azo dye is selected from the group consisted of Food Red 3, Food Red 9, and Food Black 1;
a cathode electrode; and
an electrolyte layer disposed between the photo-sensitized anode and the cathode electrodes.

20. The DSSC according to claim 19, wherein the triarylmethane dye is the Food Yellow 13 or the Food Red 14.

21. The DSSC according to claim 19, wherein the transparent substrate is made of glass or plastic.

22. The DSSC according to claim 19, wherein the transparent substrate comprises a patterned circuit layer.

23. The DSSC according to claim 19, wherein the cathode electrode is made of a material of platinum, gold, carbon or an electrically conductive polymer.

24. The DSSC according to claim 23, wherein the electrically conductive polymer is polypyrrole, polyaniline or polythiophene.

25. The DSSC according to claim 19, wherein the electrolyte layer is a liquid-, gel- or solid-state, and the electrolyte layer comprises an acetonitrile solution containing iodine, lithium iodide and 4-isobutyl pyridine.
